(19) United States
(12) Patent Application Publication
(10) Pub. No.: US 2007/0221983 A1
(43) Pub. Date: Sep. 27, 2007

(54) Dual gate memory with fast erase

(76) Inventor: Bohumil Lojek, Colorado Springs, CO (US)

Correspondence Address: SCHNECK & SCHNECK, P.O. BOX 2-E, SAN JOSE, CA, 95109-0005, US

(21) Appl. No.: 11/389,390

(22) Filed: Mar. 24, 2006

(51) Int. Cl. H01L 29/788

(52) U.S. Cl. 257/315

(57) ABSTRACT

An electronic non-volatile memory device comprising a base substrate doped with a source region and a drain region. The base substrate can be, for example, a silicon wafer with implanted source and drain regions. A channel region is disposed between the source region and the drain region with a floating gate formed substantially over the channel region. The floating gate may be comprised of a plurality of nanocrystals. A control gate is formed over the nanocrystal floating gate with an erase gate disposed between the nanocrystal floating gate and the control gate. The separate erase gate allows for low voltage operation coupled with a fast erase speed.

### TECHNICAL FIELD

The present invention relates to a semiconductor nonvolatile memory device and a method of production of the same. The present invention more particularly relates to a semiconductor nonvolatile memory device having a nanocrystal-based charge storage component with a control gate and an erase gate.

### BACKGROUND ART

Currently, semiconductor nonvolatile memory devices are being actively developed. Research and development is being conducted into various structures and configurations primarily focusing on Flash memories with a floating gate structure. Flash memories may be roughly classified into a NAND type and a NOR type array from the viewpoint of the cell configuration.

Of the two classifications of Flash memories, the NAND type array connects a plurality of memory cells in series and has common selection transistors and bit lines. Random access is not possible because of the structure. When a charge is stored in a charge storage layer, the stored charge produces an electric field. As a result of the electric field, the threshold voltage of the memory transistor changes. Due to this threshold voltage change, storage of data becomes possible. For example, data may be erased by storing a charge in the charge storage layer, and data may be written by discharging the charge stored in the charge storage layer. The charge storage layer thus has a function of holding a charge.

U.S. Pat. No. 6,005,270 to Noguchi describes a semiconductor nonvolatile memory device capable of functioning with a reduced operating voltage, such as an erase voltage. A thin film transistor acts as a memory transistor and is formed with a semiconductor layer having a channel formation region formed on an insulating substrate made of glass or plastic. A charge storage layer is formed on the semiconductor layer, a control gate is formed above the charge storage layer, and source and drain regions are formed connected to the channel formation region. In one embodiment of the Noguchi device, the charge storage layer contains nanocrystals made of conducting particles having an average diameter of 20 Å to 50 Å in diameter. Erase gates are formed at a lower layer of the semiconductor layer via a lower gate insulating film thereby forming a NAND type non-volatile memory device which is capable of batch erasing either the entire memory array or for erasing sectors in units of blocks. The Noguchi device thus requires a floating gate located distally to the control gate (i.e., layers are formed such that the erase gate is formed, followed by a dielectric separation layer, the floating gate, a second dielectric separation layer, and the control gate). Noguchi therefore requires the floating gate be located between the control gate and the erase gate, thus leading to some fabrication difficulties in addition to an increased number of processing steps. Noguchi also adopts the traditional Flash memory array arrangement whereby memory transistors are erased in batches or sectors.

With reference to FIG. 1, a typical prior art memory transistor includes a base substrate 101 that is capacitively coupled to a floating gate 103, containing a floating gate charge, Q_{f}, and a control gate 105. A first effective capacitance is obtained between the control gate 105 and the floating gate 103. A second effective capacitance is obtained between the floating gate 103, and the base substrate 101. An electric field, E₁, generated through a control gate voltage, V_{cg}, is thus defined by a coupling ratio between the control gate 105, the floating gate 103, and the base substrate 101. In other words, for a given control gate voltage, V_{cg}, applied to the control gate 105, the electric field, E₁, will be defined by to the coupling ratio between the control gate 105 and the floating gate 103.

With reference to FIG. 2, another prior art memory transistor based on a usage of nanocrystals rather than a floating gate includes a base substrate 101 that is capacitively coupled to a control gate 105 through a layer of nanocrystals 203. In this case, an electric field, E₂, generated through a control gate voltage, V_{cg}, is thus defined by a coupling ratio between the control gate 105, each of the plurality of nanocrystals contained in the nanocrystal layer 203, and the base substrate 101. Therefore, a given control gate voltage, V_{cg}, applied to the control gate 105 increases the electric field, E₂, due to the coupling ratio between the control gate 105 and each of the plurality of nanocrystals in the nanocrystal layer 203.

However, none of the prior art systems described is able to effectively increase an electric field strength from an applied control gate voltage to the substrate, lower operational voltages, and shorten erase times. Nor can the prior art ensure low leakage effects of a charge storage layer or ensure both ease of fabrication and a reduced layout area. Further, the prior art does not allow random access of individual memory transistors in an array.

### SUMMARY

In an exemplary embodiment of the present invention, a memory transistor incorporates a nanocrystal layer to hold an electronic charge, while a tunnel dielectric layer, which may be an integral portion of the nanocrystal layer, and a second dielectric layer function to seal the charge in the nanocrystal layer. Applying appropriate voltages to a control gate, an erase gate, and source and drain diffusion regions in a substrate, a Fowler Nordheim type tunnel current is produced; electrons are injected either to or from the substrate through the tunnel dielectric layer, and into or from a plurality of nanocrystals contained in the nanocrystal layer. When storing a charge in the nanocrystal layer, an electric field is generated due to the stored charge. This stored charge changes a threshold voltage of the transistor, so the transistor becomes a memory transistor whereby storage of data becomes possible. For example, data can be erased by storing a charge in the nanocrystal layer, and data can be written by releasing the charge stored in the nanocrystal layer. Adding the erase gate, located between the control gate and the nanocrystal layer, allows a lower erase voltage with shorter erase times to be obtained.

In one embodiment, the present invention is an electronic non-volatile memory device, comprising a base substrate doped with a source region and a drain region. The base substrate can be, for example, a silicon wafer with implanted source and drain regions. A channel region is disposed between the source region and the drain region with a floating gate formed substantially over the channel region. The floating gate may be comprised of a plurality of nanocrystals. A control gate is formed over the nanocrystal floating gate with an erase gate disposed between the nanocrystal floating gate and the control gate.

The present invention is also a non-volatile memory array where the array comprises a plurality of non-volatile memory transistors arranged in a plurality of rows and columns. Each of the plurality of non-volatile memory transistors includes:

(i) a base substrate doped with a source region and a drain region;

(ii) a channel region disposed between the source region and the drain region;

(iii) a floating gate formed substantially over the channel region;

(iv) a control gate formed over the floating gate; and

(v) an erase gate disposed between the floating gate and the control gate.

The array further includes a plurality of wordlines wherein each of the plurality of wordlines is coupled to the erase gate of each of the plurality of non-volatile memory transistors arranged in a row. A plurality of erase lines is coupled to the control gate of each of the plurality of non-volatile memory transistors arranged in a row; and a plurality of pairs of bitlines is coupled to each of the each of the plurality of non-volatile memory transistors arranged in a column such that a first of the pair of bitlines is coupled to the source regions of each of the plurality of non-volatile memory transistors in the column and a second of the pair of bitlines is coupled to the drain regions of each of the plurality of non-volatile memory transistors in the column. Each of the memory transistors is thus directly addressable (i.e., a true random access non-volatile memory array). Further, no select transistor is required thus reducing an overall layout area.

The present invention is also a method of fabricating a non-volatile electronic memory device where the method comprises selecting a base substrate (e.g., a silicon wafer), doping portions on a first surface of the substrate to provide a source region and a drain region, depositing a floating gate layer over at least a portion of the first surface, and forming an erase gate layer wherein the erase gate layer is located above both the first surface and the floating gate layer. A dielectric layer and a control gate layer are then respectively formed over the erase gate layer.

### BRIEF DESCRIPTION OF THE DRAWINGS

FIG. 1 is a diagrammatic representation of a memory transistor of the prior art having a traditional floating gate.

FIG. 2 is a diagrammatic representation of a memory transistor of the prior art wherein a floating gate voltage is comprised of a plurality of nanocrystals.

FIG. 3 is an exemplary diagrammatic representation of a memory transistor of the present invention having a separate erase gate and a floating gate comprised of a plurality of nanocrystals.

FIG. 4 is an exemplary cross-sectional area of the memory transistor of FIG. 3.

FIG. 5 is an exemplary flowchart outlining process steps used to fabricate the memory transistor of FIG. 4.

FIG. 6 is an exemplary memory array utilizing the memory transistor of FIG. 4.

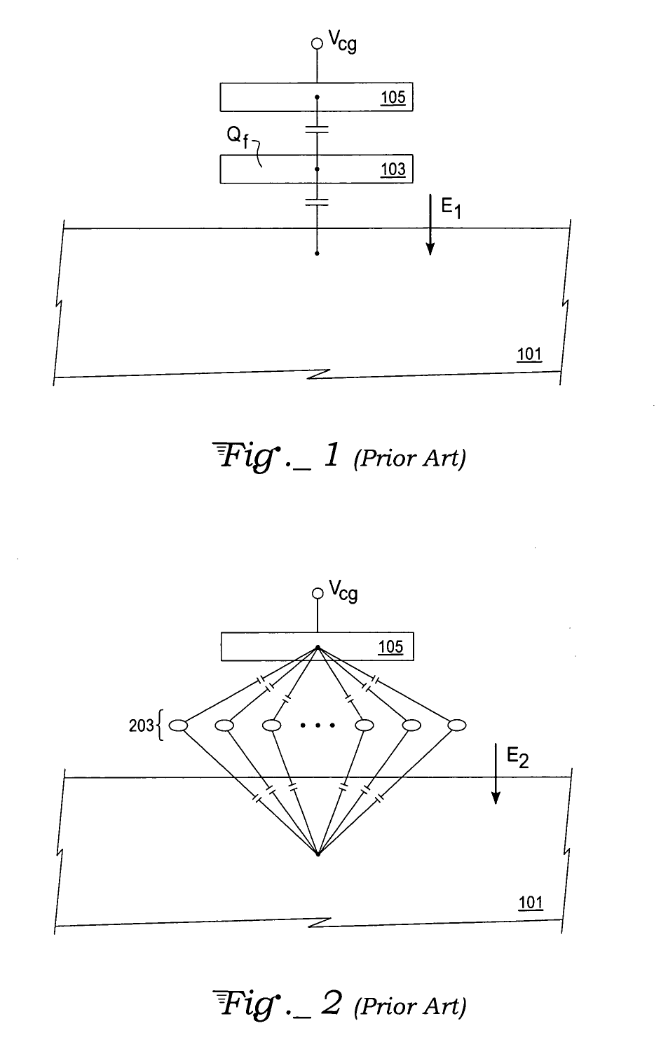

### DETAILED DESCRIPTION

In order to reduce a required thickness of a tunnel dielectric layer in an EEPROM memory device, thereby allowing lower control voltages, a uniform layer of material used for a traditional floating gate may be replaced with a plurality of nanocrystals. Nanocrystals operate as isolated charge storage elements. When combined in relatively large numbers, the plurality of nanocrystals provide adequate charge storage capacity while remaining physically isolated from each other. Any leakage which may occur with respect to a single nanocrystal through a local underlying defect does not cause charge to be drained from other nanocrystals. Lateral charge flow between nanocrystals in the floating gate can be ensured by controlling average spacing between nanocrystals by techniques known in the art and described briefly herein. Therefore, thinner tunnel dielectrics can be used in device structures employing nanocrystals. Effects of leakage occurring in thin tunnel dielectric devices with nanocrystals does not cause the loss of state information that occurs in devices that include a uniform-layer floating gate. Additionally, a separate erase gate added to the EEPROM memory device acts in combination with a control gate to increase electric field strength across the plurality of nanocrystals provides for a fast erase with minimal power.

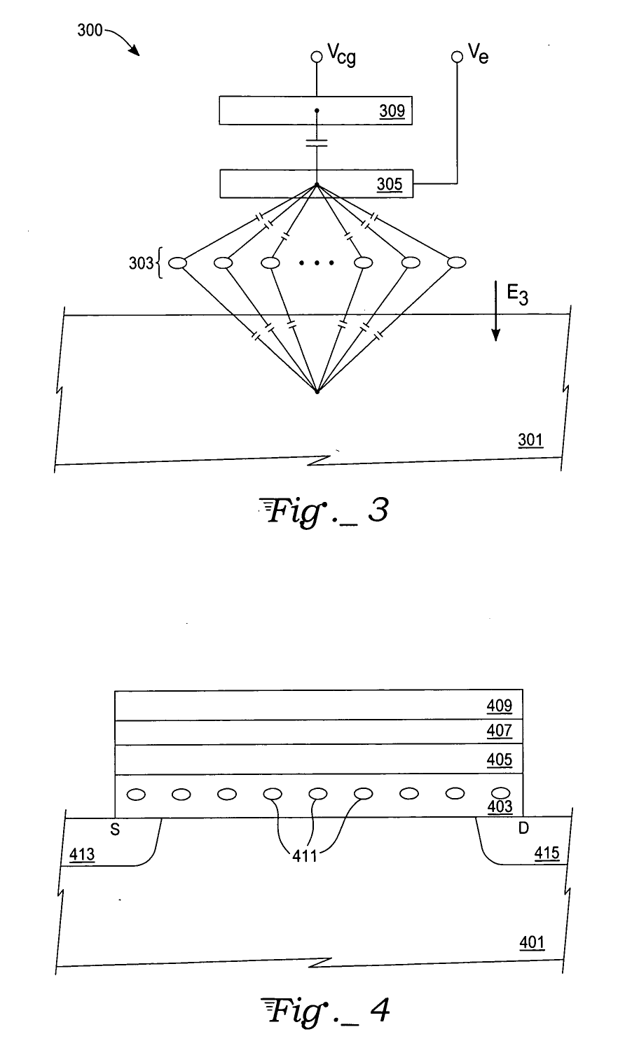

With reference to FIG. 3, a memory transistor includes a base substrate 301 that is capacitively coupled to an erase gate 305 and a control gate 309 through a layer of nanocrystals 309. A first effective capacitance is obtained between the control gate 309 and the erase gate 305. A second effective plurality of capacitances is obtained between the erase gate 305, each of the plurality of nanocrystals in the nanocrystal layer 303, and the base substrate 301. An electric field, E₃, generated through a floating gate voltage is thus defined by a coupling ratio between the control gate 309, the erase gate 305, and the nanocrystal layer 303, combined with voltages, V_{cg} and Vₑ, applied to the control gate 309 and the erase gate 305, respectively. In other words, for a given control gate voltage, V_{cg}, applied to the control gate 309, the electric field, E₃, will be increased due to the coupling ratio between the control gate 309 and the erase gate 305. Therefore, adding the erase gate to the memory transistor allows for a lower voltage for Fowler-Nordheim tunneling to occur coupled with a fast erase time.

The layer of nanocrystals 303 perform the function of a traditional floating gate of the prior art while bringing additional advantages described herein. Adding the erase gate 305 increases a strength of the electric field E₃ due to the coupling between the erase gate 305 and the control gate 309.

In FIG. 4, a cross-sectional area of the memory transistor, shown diagrammatically in FIG. 3, includes a base substrate 401, a nanocrystal layer 403, an erase gate layer 405, a dielectric layer 407, a control gate layer 409, a plurality of nanocrystals 411 contained within the nanocrystal layer 403, a source region 413, and a drain region 415. (Upon completion of fabrication, layers serve as a basis to form particular structural features in the diagrammatic representation of the memory transistor 300 (FIG. 3) and consequently have comparable element numbers. For example, the erase gate layer 405 serves to form the erase gate 305.)

The base substrate 401 may be a silicon wafer. Alternatively, the base substrate 401 may be comprised of various materials known in the semiconductor and related art fields. Such materials include other elemental group IV semiconductors, compound semiconductors (e.g., compounds of elements (e.g., silicon germanium), and compound materials from periodic table groups III-V and II-VI), quartz reticles, substrates (i.e., backplanes) for flat panel displays, or other suitable materials.

The nanocrystal layer 403 is shown as a single homogenous layer for purposes of clarity. However, the nanocrystal layer 403 may be comprised of a plurality of layers. For example, the nanocrystal layer 403 may include a thin silicon dioxide layer (not shown explicitly), serving as a tunnel dielectric layer, initially formed over the base substrate 401. Alternatively, the nanocrystal layer 403 may include a thin oxynitride or nitrided-oxide serving as a tunnel dielectric layer. In general, the tunnel dielectric is formed to a thickness and quality to prevent breakdown and leakage at operating conditions. The thin silicon dioxide layer may be, for example, 30 Å to 50 Å in thickness and can be either thermally grown or deposited by other thin-film methods known to a skilled artisan (e.g., atomic layer deposition, ALD).

Various methods for forming the plurality of nanocrystals 411 are known by one skilled in the art. For example, silicon atoms may be implanted into a dielectric material, such as silicon dioxide. A subsequent annealing step (e.g., in a rapid thermal annealer (RTA) or an excimer laser annealer (ELA) process) causes the implanted silicon atoms to group together through phase separation to form the plurality of nanocrystals 411. Alternatively, amorphous silicon may be deposited on top of the tunnel dielectric layer, followed by a subsequent annealing step to recrystallize the amorphous silicon into nanocrystals. Silicon nanocrystals may also be formed by depositing silicon in a manner whereby silicon has a very high surface diffusivity relative to its sticking coefficient. For example, silicon nanocrystals can be formed by chemical vapor deposition (CVD), (or alternatively, low-pressure CVD (LPCVD), molecular beam epitaxy (MBE), or other epitaxial processes) by decomposing silane (SiH₄) at low pressure, between 1 mTorr to 200 mTorr, at a temperature of between 250° C. to 650° C. In this silane decomposition process, a thin deposition (typically between 50 Å to 100 Å) will form small islands of silicon. If hydrogen (H₂) is included with silane during the deposition, higher pressures can be utilized and still obtain nanocrystals. Similarly known in the art are processes for producing nanocrystals comprised of compound semiconductors, such as silicon germanium (SiGe). In an alternative embodiment of the present invention, metal nanocrystals such as aluminum nanocrystals, can be formed by sputtering from a metal target at a temperature near a melting temperature of the metal target. Sputtered metal particles then agglomerate and form nanocrystals. Tungsten nanocrystals can be formed by chemical vapor deposition utilizing a reactant gas mix comprising a tungsten source gas such as tungsten hexafluoride (WF₆) and germane (GeH₄). Other techniques have focused on an LPCVD nucleation and growth process to form crystalline nanocrystals directly on the tunnel dielectric layer. Generally, nanocrystals are typically from 30 Å to 80 Å in size but other sizes have been contemplated.

In a specific exemplary embodiment, the substrate 401 is a p-type silicon wafer (or alternatively, a p-type well in a substrate). The erase gate layer 405 is polysilicon, deposited to a thickness of about 500 Å to 800 Å, while the dielectric layer 407 may be substantially comprised of silicon dioxide or silicon nitride (or, alternatively, an oxide-nitride-oxide (ONO) layer), deposited to about 60 Å to 100 Å in thickness. The control gate layer 409 is also polysilicon, deposited to a thickness of about 1000 Å to 1500 Å. The various layers may be deposited or grown by various methods known to one skilled in the art. For example, the erase gate layer 405 and the control gate layer 409 may each be deposited by chemical vapor deposition (CVD). The source 413 and drain 415 regions may be doped either by diffusion or implantation.

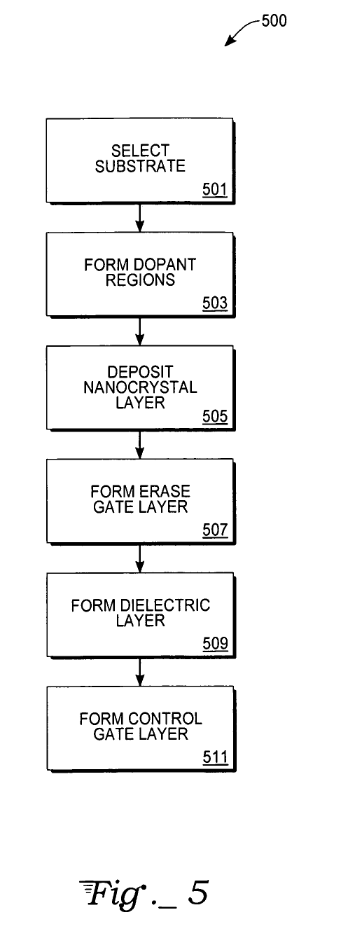

A process flowchart 500 of FIG. 5 provides a high-level flow of basic fabrication steps for producing a memory transistor of the present invention. An appropriate base substrate is selected 501. The substrate will be selected based upon an intended use of a finalized memory product. For example, a memory cell used as a component in an integrated circuit for a computer may be formed on a silicon wafer. A memory cell used for lightweight applications or flexible circuit applications, such as a cellular telephone or personal data assistant (PDA), may form the memory cell on a polyethyleneterephthalate (PET) substrate deposited with silicon dioxide and polysilicon followed by an excimer laser annealing (ELA) anneal step.

Dopant regions are formed 503 for source and drain regions. Dopant regions are typically formed using an ion implantation process but dopants may also be diffused into, for example, the silicon wafer substrate.

A nanocrystal layer is then deposited 505 onto the base substrate. Various methods for forming the nanocrystal layer are discussed with regard to FIG. 4, supra. An erase gate layer is then formed 507 over the nanocrystal layer. The erase gate is typically substantially comprised of an elemental semiconductor, such as polysilicon, but may be formed from other semiconducting or metallic materials as well. A dielectric layer is then formed 509 over the erase gate layer and may be comprised of a CVD-deposited silicon dioxide layer. A control gate layer is formed 511 over the dielectric layer and is typically comprised of the same material used to fabricate the erase gate layer. Various etching and metallization steps are completed (not shown) to finalize the circuit topology and circuit interconnects. Such steps are known to a person of skill in the art.

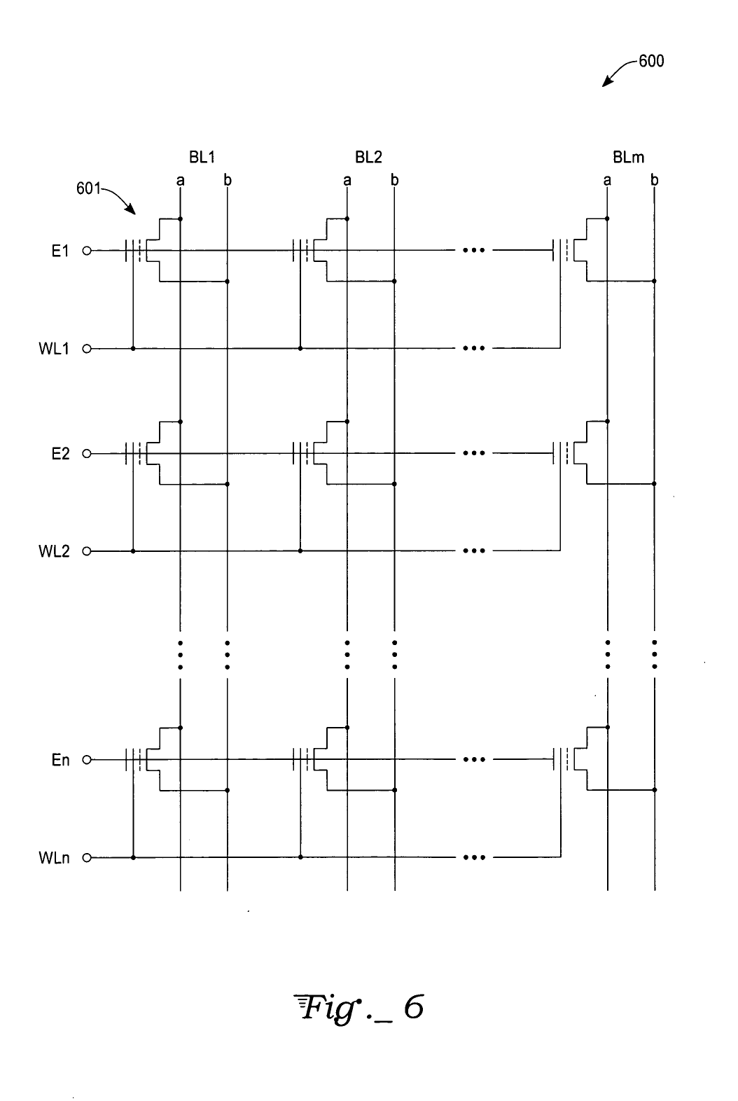

With reference to FIG. 6, an exemplary memory array 600 includes a plurality of memory transistors 601. Each of the plurality of memory transistors 601 is coupled to one of a plurality of erase lines (E1, E2, . . . , En) and wordlines (WL1, WL2, . . . , WLn). A control gate of each of the plurality of memory transistors 601 is coupled to one of the plurality of erase lines (E1, E2, . . . , En) while an erase gate of each of the plurality of memory transistors 601 is coupled to one of the plurality of wordlines (WL1, WL2, . . . , WLn). Additionally, each of the plurality of memory transistors is coupled to a plurality of dual bitlines (BL1, BL2, . . . , BLm).

In a specific exemplary arrangement, the plurality of dual bitlines is arranged such that there are eight bitline pairs, thus forming a byte. The plurality of dual bitlines consequently form pairs of bitlines (bitline “a” and bitline “b”). The plurality of dual bitlines is thus arranged such that there are eight bitline pairs (i.e., m=8), thus forming an eight-bit byte.

Several unique features of the exemplary memory array 600 are readily apparent. Each of the plurality of memory transistors 601, each containing a separate erase gate, is coupled to four lines, a wordline, an erase line, and two independent bitlines (“a” and “b”). Since each of the plurality of memory transistors 601 has a drain and a source separately coupled to the independent bitlines, there is no need for a select transistor as each of the plurality of memory transistors 601 can be directly and randomly accessed. Thus, eliminating the select transistor reduces overall real estate requirements for the exemplary memory array 600 and allows access to each of the plurality of memory transistors 601 separately.

Voltages for programming, erasing, and reading memory are performed similarly to a conventional memory cell except that program and erase voltages are lowered by a factor determined by a capacitance coupling ratio. The coupling ratio depends upon the cell size and dielectric thicknesses. In a typically well-optimized cell, the program and erase voltages may be reduced by as much as two volts or more.

In the foregoing specification, the present invention has been described with reference to specific embodiments thereof. It will, however, be evident to a skilled artisan that various modifications and changes can be made thereto without departing from the broader spirit and scope of the invention as set forth in the appended claims. For example, skilled artisans will appreciate that other types of semiconducting and insulating materials other than those listed may be employed. Additional particular process fabrication and deposition techniques, such as low pressure chemical vapor deposition (LPCVD), molecular-beam epitaxy (MBE), ultra-high vacuum CVD (UHCVD), and low pressure tetra-ethoxysilane (LPTEOS) may be readily employed for various layers and still be within the scope of the present invention. Although the exemplary embodiments describe particular types of dielectric and semiconductor materials, one skilled in the art will realize that other types of materials and arrangements of materials may also be effectively utilized and achieve the same or similar advantages. Also, the substrate itself may be comprised of a non-semiconducting material, for example, a quartz reticle with a deposited and doped polysilicon layer (potentially coupled with an anneal step, such as rapid-thermal annealing (RTA) or excimer laser annealing (ELA)). The erase gate may additionally be advantageously used with either a nanocrystal layer as described or a traditional single-layer floating gate. Additionally, although the exemplary embodiments are described in terms of an EEPROM memory cell integrated circuit device, a person of ordinary skill in the art will recognize that other integrated circuit devices may readily benefit from the fabrication process described herein as well. The specification and drawings are, accordingly, to be regarded in an illustrative rather than a restrictive sense.

What is claimed is:

1. An electronic non-volatile memory device, comprising:
a base substrate doped with a source region and a drain region;
a channel region disposed between the source region and the drain region;
a floating gate formed substantially over the channel region;
a control gate formed over the floating gate; and
an erase gate disposed between the floating gate and the control gate.

2. The electronic non-volatile memory device of claim 1 wherein the floating gate is comprised of a plurality of nanocrystals.

3. The electronic non-volatile memory device of claim 2 wherein each the plurality of nanocrystals is substantially comprised of silicon.

4. The electronic non-volatile memory device of claim 2 wherein each the plurality of nanocrystals is substantially comprised of silicon germanium.

5. The electronic non-volatile memory device of claim 2 wherein each the plurality of nanocrystals is substantially comprised of tungsten.

6. The electronic non-volatile memory device of claim 2 wherein each the plurality of nanocrystals is substantially comprised of aluminum.

7. The electronic non-volatile memory device of claim 2 wherein each the plurality of nanocrystals is substantially comprised of a metallic material.

8. The electronic non-volatile memory device of claim 1 wherein the base substrate is silicon.

9. The electronic non-volatile memory device of claim 1 wherein the base substrate is silicon germanium.

10. An electronic non-volatile memory device, comprising:
a base substrate doped with a source region and a drain region;
a channel region disposed between the source region and the drain region;
a floating gate formed substantially over the channel region, the floating gate being comprised of a plurality of nanocrystals;
a control gate formed over the nanocrystal floating gate; and
an erase gate disposed between the nanocrystal floating gate and the control gate.

11. The electronic non-volatile memory device of claim 10 wherein each the plurality of nanocrystals is substantially comprised of silicon.

12. The electronic non-volatile memory device of claim 10 wherein each the plurality of nanocrystals is substantially comprised of silicon germanium.

13. The electronic non-volatile memory device of claim 10 wherein each the plurality of nanocrystals is substantially comprised of tungsten.

14. The electronic non-volatile memory device of claim 10 wherein each the plurality of nanocrystals is substantially comprised of aluminum.

15. The electronic non-volatile memory device of claim 10 wherein each the plurality of nanocrystals is substantially comprised of a metallic material.

16. The electronic non-volatile memory device of claim 10 wherein the base substrate is silicon.

17. The electronic non-volatile memory device of claim 10 wherein the base substrate is silicon germanium.

18. An electronic non-volatile memory device, comprising:
a base substrate having a semiconducting layer, the semiconducting layer being doped with a source region and a drain region;
a channel region disposed between the source region and the drain region;
a floating gate formed substantially over the channel region;
a control gate formed over the floating gate; and
an erase gate disposed between the floating gate and the control gate.

19. The electronic non-volatile memory device of claim 18 wherein the floating gate is comprised of a plurality of nanocrystals.

20. The electronic non-volatile memory device of claim 19 wherein each the plurality of nanocrystals is substantially comprised of silicon.

21. The electronic non-volatile memory device of claim 19 wherein each the plurality of nanocrystals is substantially comprised of silicon germanium.

22. The electronic non-volatile memory device of claim 19 wherein each the plurality of nanocrystals is substantially comprised of tungsten.

23. The electronic non-volatile memory device of claim 19 wherein each the plurality of nanocrystals is substantially comprised of aluminum.

24. The electronic non-volatile memory device of claim 19 wherein each the plurality of nanocrystals is substantially comprised of a metallic material.

25. A non-volatile memory array, comprising:
a plurality of non-volatile memory transistors arranged in a plurality of rows and columns, each of the plurality of non-volatile memory transistors including:
(i) a base substrate doped with a source region and a drain region;
(ii) a channel region disposed between the source region and the drain region;
(iii) a floating gate formed substantially over the channel region;
(iv) a control gate formed over the floating gate; and
(v) an erase gate disposed between the floating gate and the control gate
a plurality of wordlines, each of the plurality of wordlines coupled to the erase gate of each of the plurality of non-volatile memory transistors arranged in a row;
a plurality of erase lines, each of plurality of erase lines coupled to the control gate of each of the plurality of non-volatile memory transistors arranged in a row; and
a plurality of pairs of bitlines, each of the plurality of pairs of bitlines coupled to each of the each of the plurality of non-volatile memory transistors arranged in a column such that a first of the pair of bitlines is coupled to the source regions of each of the plurality of non-volatile memory transistors in the column and a second of the pair of bitlines is coupled to the drain regions of each of the plurality of non- volatile memory transistors in the column.

26. The non-volatile memory array of claim 25 wherein the floating gate is comprised of a plurality of nanocrystals.

27. The non-volatile memory array of claim 26 wherein each the plurality of nanocrystals is substantially comprised of silicon.

28. The electronic non-volatile memory device of claim 26 wherein each the plurality of nanocrystals is substantially comprised of silicon germanium.

29. The electronic non-volatile memory device of claim 26 wherein each the plurality of nanocrystals is substantially comprised of tungsten.

30. The electronic non-volatile memory device of claim 26 wherein each the plurality of nanocrystals is substantially comprised of aluminum.

31. The electronic non-volatile memory device of claim 26 wherein each the plurality of nanocrystals is substantially comprised of a metallic material.

32. The non-volatile memory array of claim 25 wherein the base substrate is silicon.

33. The non-volatile memory array of claim 25 wherein the base substrate is silicon germanium.

34. The non-volatile memory array of claim 25 wherein the memory array does not contain a select transistor.

35. A method of fabricating a non-volatile electronic memory device, the method comprising:
selecting a base substrate;
doping portions on a first surface of the substrate to provide a source region and a drain region;
depositing a floating gate layer over at least a portion of the first surface;
forming an erase gate layer, the erase gate layer being located above both the first surface and the floating gate layer;
forming a dielectric layer over the erase gate layer; and
forming a control gate layer over the dielectric layer.

36. The method of claim 35 wherein the floating gate layer is formed by depositing a nanocrystal layer comprised of a plurality of nanocrystals.

37. The method of claim 36 wherein the floating gate is formed by decomposing silane at low pressure, thus forming silicon nanocrystals.

38. The method of claim 35 wherein the base substrate is selected to be silicon.

39. The method of claim 35 wherein the base substrate is selected to be silicon germanium.

40. A method of fabricating a non-volatile electronic memory device, the method comprising:
selecting a base substrate;
depositing a semiconducting layer over the base substrate;
doping portions of the semiconducting layer to provide a source region and a drain region;
depositing a floating gate layer over at least a portion of the first surface;
forming an erase gate layer, the erase gate layer being located above both the first surface and the floating gate layer;
forming a dielectric layer over the erase gate layer; and
forming a control gate layer over the dielectric layer.

41. The method of claim 40 further comprising annealing the semiconducting layer.

42. The method of claim 41 wherein the annealing step is performed by applying localized heat to the semiconducting layer through an application of excimer laser annealing.

43. The method of claim 41 wherein the annealing step is performed by applying heat to the semiconducting layer through an application of rapid thermal annealing.

44. The method of claim 40 wherein the semiconducting layer is polysilicon deposited by chemical vapor deposition.
